(19) United States
(12) Patent Application Publication
(10) Pub. No.: US 2016/0035914 A1
(43) Pub. Date: Feb. 4, 2016

(54) FILTER COATING DESIGN FOR OPTICAL SENSORS

(71) Applicant: ANALOG DEVICES, INC., Norwood, MA (US)

(72) Inventor: Shrenik Deliwala, Andover, MA (US)

(73) Assignee: ANALOG DEVICES, INC., Norwood, MA (US)

(21) Appl. No.: 14/612,649

(22) Filed: Feb. 3, 2015

Related U.S. Application Data
(60) Provisional application No. 62/031,711, filed on Jul. 31, 2014.

(51) Int. Cl. H01L 31/0232; H01L 31/18; H01L 31/028

(52) U.S. Cl. CPC H01L 31/02327; H01L 31/028; H01L 31/1804

(57) ABSTRACT

A silicon-based sensor with an integrated multilayer metal-dielectric filter coating for providing a UV transmission curve of interest is disclosed. The sensor includes a silicon-based photodiode and a filter coating integrated with the silicon-based photodiode and comprising a plurality of filter pairs stacked over the silicon-based photodiode. Each filter pair comprises a dielectric layer and a metal layer. The dielectric layers and the metal layers of the plurality of filter pairs are stacked in an alternating fashion. A thickness of the metal layer in at least one filter pair is different from a thickness of the metal layer in at least one other filter pair. A thickness of the dielectric layer in at least one filter pair is different from a thickness of the dielectric layer in at least one other filter pair.

### PRIORITY DATA

This application is a non-provisional of U.S. Provisional Patent Application Ser. No. 62/031,711, filed Jul. 31, 2014, which is hereby incorporated by reference in its entirety.

### TECHNICAL FIELD OF THE DISCLOSURE

The present invention relates to the field of optical sensors, in particular to a silicon-based sensor with an integrated multilayer metal-dielectric filter coating for providing an ultraviolet (UV) transmission curve of interest.

### BACKGROUND

Optical sensors are ubiquitous in electronics from instrumentation equipment, to consumer products. One type of an optical sensor is tailored to making UV measurements. UV measurements are important for flame detection, UV index (UVI) which is an internationally accepted measure of harmful effect of UV rays on human skin, and other action curves such as Vitamin D production curves, photosynthesis inhibition curves, DNA damage action, tanning effectiveness curves, etc. ¹ ¹ See http://www.photobiology.com/UVR98/wongrev/

In many of these cases, weighted intensity (in W/m²) at specific wavelengths of the UV radiations have to be measured, where the weights corresponds to the curve of interest. The curve of interest represents a weighting function for UV measurements when computing an index such as UVI. To facilitate UV measurements and calculations, optical sensors are usually provided with a material that can filter light in a way that more or less corresponds to the curve of interest. Many optical sensors which can provide such a function tend to be very expensive, and the size of these optical sensors are too large to be used in compact electronic devices.

### OVERVIEW

One aspect of the present invention relates to a silicon-based sensor with an integrated multilayer metal-dielectric filter coating for providing a UV transmission curve of interest (i.e., a specific or a defined transmission curve). The sensor includes a silicon-based photodiode and a filter coating integrated with the photodiode and comprising a plurality of filter pairs stacked (disposed) over the photodiode. Each filter pair comprises a dielectric layer and a metal layer. The dielectric layers and the metal layers of the plurality of filter pairs are stacked in an alternating fashion (i.e., when a layer of one filter pair is stacked or disposed over a layer of another filter pair, one of these layers is a dielectric layer and the other layer is a metal layer). A thickness of the metal layer in at least one filter pair is different from a thickness of the metal layer in at least one other filter pair. Similarly, a thickness of the dielectric layer in at least one filter pair is different from a thickness of the dielectric layer in at least one other filter pair.

Embodiments of the present invention are based on an insight that, using a simple metal-dielectric film pairs stacked over one another, a UV filter coating can be provided that is advantageously compatible with standard Complementary Metal Oxide Semiconductor (CMOS) fabrication processes, including specialized processes for making silicon-based photodiodes (SiPDs) commonly used for a variety of sensors. Using a process to provide a UV filter integrated (i.e., monolithic) with a silicon-based photodiode enables providing sensors for different spectral regions in a single compact package, where the ease of depositing a UV filter coating as described herein allows the UV filter to be localized where this particular type of sensor is needed. Such a package could then comprise a plurality of monolithic, multipurpose optical sensors that detect not only UV, but also visible (VIS), infrared (IR), and near infrared (NIR). Such a package could also comprise integrated silicon-based sensors having other functionalities, such as e.g. gesture sensors or ambient light sensors.

Embodiments of the present invention are further based on an insight that, within the UV filter coating, having the thicknesses of metal and dielectric layers being different in different layers allows each pair (also referred to herein as a “stack”) to contribute to a filter response at a different wavelength and angle of incidence, thereby enabling a UV filter coating that can provide a particular transmission curve of interest, such as e.g. an Erythema curve, a Photopic curve, a Photosynthesis inhibition curve, a Vitamin D production curve, a bandpass response for passing Ultraviolet A light (UVA curve), or a bandpass response for passing Ultraviolet B light (UVB curve).

In an embodiment, a thickness of the metal layer in at least one filter pair may be selected so that total power transmitted in the visible/infrared (IR) or near infrared (NIR) spectrum is below 10⁻⁴, preferably below 10⁻⁵. In such an embodiment, the visible/IR/NIR spectrum could be considered to comprise wavelengths greater than 400 nanometers (nm), e.g. in the range 400-1000 nm.

In an embodiment that could be alternative or additional to any of the embodiments above, a top surface of the filter coating could be made uneven (e.g., rippled or wavy) in order to randomize angles of incidence, thereby effectively diffusing light transmitted through the filter coating. In one example, an uneven top surface may be formed by a pattern of a dielectric material deposited within or over the silicon-based photodiode prior to providing the plurality of filter pairs stacked over the silicon-based photodiode. In another example, an uneven top surface may be formed by a pattern etched within the silicon-based photodiode prior to providing the plurality of filter pairs stacked over the silicon-based photodiode.

In an embodiment that could be alternative or additional to any of the embodiments above, the sensor can be made less sensitive to angles of incidence by either simulating the effects of diffuser on the substrate itself or by using a traditional diffusing material on top of the filter coating.

In an embodiment that could be alternative or additional to any of the embodiments above, a thickness of the metal layer in at least one filter pair and/or a thickness of the dielectric layer in at least one filter pair may be selected to provide the transmission curve of interest, such as e.g. a Erythema curve, a Photopic curve, a Photosynthesis inhibition curve, a Vitamin D production curve, a bandpass response for passing Ultraviolet A light, or a bandpass response for passing Ultraviolet B light.

In an embodiment that could be alternative or additional to any of the embodiments above, the metal layers may comprise aluminum layers. Using aluminum may provide multiple advantages such as e.g. aluminum being a well-known fabrication material compatible with silicon processing, low cost, and multiple methods of deposition that produce good quality optical films being available. The thickness of such layers is preferably below 40 nm. In other embodiments, other metals, such as e.g. platinum or silver, or metal alloys may be used as metal layers of the filter pairs.

In an embodiment that could be alternative or additional to any of the embodiments above, the dielectric layers may include one or more of the following materials: hafnium dioxide, silicon nitride, aluminum oxide, and oxides of tantalum.

In an embodiment that could be alternative or additional to any of the embodiments above, the sensor may further include a first dielectric layer and a second dielectric layer sandwiching the plurality of filter pairs.

Another aspect of the present invention relates to a device comprising a substrate, a first silicon-based photodiode provided in or on the substrate, one or more second silicon-based photodiodes provided in or on the substrate, and a filter coating as described above, where the one or more second silicon-based photodiodes form one or more sensors other than sensors for providing the UV transmission curve of interest.

In an embodiment, the one or more second silicon-based photodiodes include one or more of a gesture sensor, a photopic sensor, an ambient light sensor, a heartrate detector sensor, a red light sensor, and a proximity sensor.

In an embodiment, the substrate may be a silicon on insulator (SOI) substrate or a bulk silicon substrate.

Yet another aspect of the present invention relates to a method for fabricating a silicon-based sensor with an integrated multilayer metal-dielectric filter coating for providing a UV transmission curve of interest, as described above. The method includes steps of providing a silicon-based photodiode and providing a filter coating integrated with the silicon-based photodiode by stacking a plurality of filter pairs of the filter coating over the silicon-based photodiode, where each filter pair comprises a dielectric layer and a metal layer, the dielectric layers and the metal layers of the plurality of filter pairs are stacked in an alternating fashion, a thickness of the metal layer in at least one filter pair is different from a thickness of the metal layer in at least one other filter pair, and a thickness of the dielectric layer in at least one filter pair is different from a thickness of the dielectric layer in at least one other filter pair.

In one embodiment, the method may further include a step of depositing a pattern of a dielectric material within or over the silicon-based photodiode prior to stacking the plurality of filter pairs stacked over the silicon-based photodiode in order to ensure that the top surface of the filter coating is uneven (e.g. rippled or wavy). In another embodiment, the method may further include a step of etching a pattern within the silicon-based photodiode prior to providing the plurality of filter pairs stacked over the silicon-based photodiode in order to ensure that the top surface of the filter coating is uneven.

In an embodiment, the method may further include a step of selecting a thickness of the metal layer in at least one filter pair and/or a thickness of the dielectric layer in at least one filter pair to provide the transmission curve of interest.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 is a graph showing an Erythema curve and three sunlight spectra result of differing amounts of ozone column in the upper atmosphere;

FIG. 2 shows a multilayer structure of a plurality of photodiodes, according to some embodiments of the disclosure;

FIG. 3 shows a detailed multilayer structure of an optical sensor with an improved coating, according to some embodiments of the disclosure;

FIG. 4 is a graph showing an Erythema curve and transmission curves of light being transmitted at an angle of 0°, 15°, and 30° using an optical sensor with an improved filter coating, according to some embodiments of the disclosure;

FIG. 5A shows a detailed multilayer structure of an optical sensor with another improved filter coating having a diffuser, according to some embodiments of the disclosure;

FIG. 5B shows a 3-dimensional model of the optical sensor with an improved filter coating having a diffuser such as the one shown in FIG. 5A, according to some embodiments of the disclosure;

FIG. 5C shows a detailed multilayer structure of an optical sensor with yet another improved filter coating having a diffuser, according to some embodiments of the disclosure;

FIG. 6 is a graph showing an Erythema curve and transmission curves of light being transmitted at an angle of 0°, 15°, and 30° using an optical sensor with an improved filter coating having a diffuser, according to some embodiments of the disclosure;

FIG. 7 is a graph comparing ideal UVI results versus UVI results obtained using an optical sensor with an improved filter coating having a diffuser, according to some embodiments of the disclosure;

FIG. 8 is a graph showing an exemplary transmission curve of an optical sensor with an improved filter coating, according to some embodiments of the disclosure; and

FIG. 9 is a graph showing an ideal transmission curve of a photopic filter and a transmission curve of an optical sensor with an improved filter coating, according to some embodiments of the disclosure.

### DESCRIPTION OF EXAMPLE EMBODIMENTS OF THE DISCLOSURE

### Example Challenges in Building a Suitable UV Sensor

Typically, one important challenge in building a UV sensor is providing an appropriate filter or filter coating to make a sensor with a transmission curve that more or less resembles a curve of interest, such as a Erythema curve. Other challenges involve using an appropriate material or substrate for the photodiode. Specifically, a UV sensor is considered challenging to build using SiPDs since SiPDs are able to detect radiation from UV to infrared (IR). For a UV sensor to work with a SiPD, a special optical filter coatings have to be applied to the SiPD so that practically everything but the narrow band of UV light of interest is strongly rejected. Despite the availability of advanced processes and low cost in using SiPD, providing an appropriate coating or filter remains a challenge. With many other types of sensors such as ambient light sensors or gesture sensors being provided using SiPD, it has become more desirable to also find a way to provide a UV sensor using SiPD so that all the different types of sensors can be fabricated and provided in one single package or die. If one of the sensors amongst many on the SiPD sensor die is a UV sensor, then the UV coating for measuring a specific UV function such as Vitamin D dose, UVI etc. needs to have high blocking of VIS/NIR (e.g. 10⁻⁴ or more) on the UV sensor while other sensors continue to monitor other parts of the spectrum. Therefore, while some research groups have shown metal dielectric stacks with a reasonably good UV transmission, such stacks have extremely poor light blocking in the VIS/NIR spectrum, on the order of less than 10⁻², making it extremely difficult, if not impossible, to use such a coating based on Ag/glass combination for multi-use sensor application. In such a case, external filters could be used to complement the performance of the metal-dielectric stacks, but may be impractical as it is very likely that the external filters would have to be separated from the sensor surface by the height of the wire bonds, which is typically ˜100 μm. Such a gap between the external filters and the underlying sensors is highly undesirable because the external filters will have to be matched and aligned to the pattern of underlying sensors and because the gap means that unwanted light can easily leak into the UV sensor.

UV filters with desirable properties using conventional dielectric thin films are available commercially. They are typically deposited on a glass substrate, but can also be deposited on silicon wafers. However, in order to provide an appropriate UV response and sufficiently suppress transmission of visible and NIR light, the designs become extremely challenging and require use of 20-100 layers, all deposited with very high precision. Furthermore, even if such a design could be practically developed and deposited on a silicon wafer, removing deposited films from other regions where these films are not needed, such as e.g. bond pads or other detectors, becomes extremely challenging and compromises robustness of the fabrication process. Consequently, various types of commercial UV radiation measuring equipment, some even employing SiPDs, use separate stacks of filters deposited on glass. Some filters in the stack provide UV filter, while the others provide suppression of visible and NIR light. A major drawback of such an approach is that it becomes impossible to construct a multiuse sensor in which parts of the same die could be used for different optical functions.

With the conventional approaches for building UV sensors as described above, building a UV sensor that has a response suitable (e.g. following) a particular transmission curve of interest, such as e.g. an Erythema curve, necessitates design that is even more complicated and less robust, while still failing to yield reasonably adequate results.

Understanding UV Index (UVI)

The UV Index is an internationally defined standard that weighs sunlight according to the following formula:

$$U V I = \frac{1}{25 \frac{mW}{{m}^{2}}} {\int }_{298}^{400} {I}_{sun} ( λ ) E ( λ ) d λ ,$$

where the sunlight intensity I(λ) is measured in Wm⁻²nm⁻¹ and the weighting factor E(λ) is referred to, interchangeably, as a Erythema curve, a McKinlay-Diffey action spectra, or a CIE-Action. The Erythema curve provides an internationally accepted weight representing potential for the energy at a particular wavelength to cause damage to the skin.

The sunlight in the UV region of the spectrum is sensitive to the amount of ozone in the atmosphere, aerosols, as well as clouds etc. The integral ∫₂₉₈⁴⁰⁰Iₛᵤₙ(λ)E(λ)dλ has the units of W/m² and is often measured by UV meters in the units of μW/cm². The scale factor between the two is:

$$UVBio ( \frac{µW}{{cm}^{2}} ) = 2.5 U V I .$$

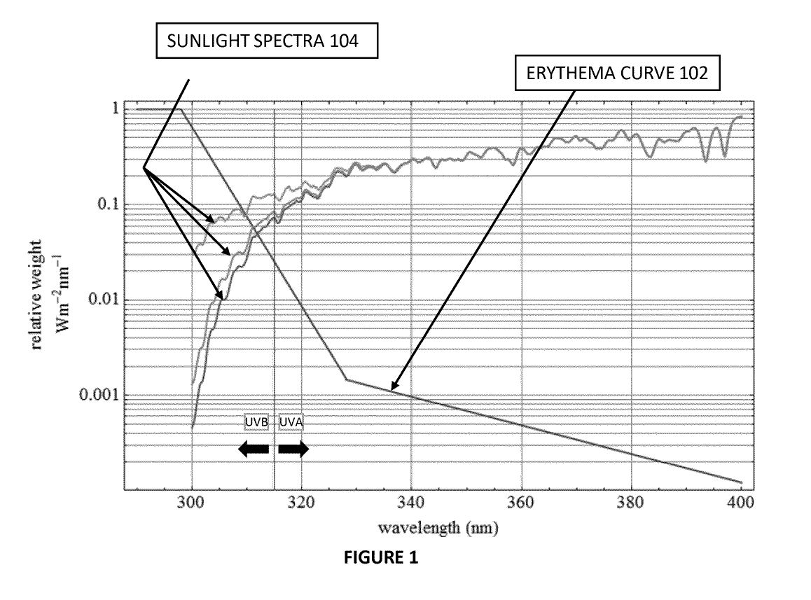

FIG. 1 is a graph showing an Erythema curve (E(λ)) 102 and three sunlight spectra (Iₛᵤₙ(λ)) 104 resulting from differing amounts of ozone column in the upper atmosphere. The UVI index would depend on a product of Iₛᵤₙ(λ) and E(λ).

As is illustrated in FIG. 1, in the UV region, the sunlight is increasing by almost three orders of magnitude whereas the Erythema curve is decreasing by roughly three orders of magnitude. This relationship between the sunlight and the weighting curve makes it quite difficult to obtain an accurate UVI measurement. The measurement is further complicated by the fact that, besides ozone, the UV radiation reaching Earth is affected by aerosol particles, dust etc.

Improved Filter Coating

Embodiments of the present disclosure provide a silicon-based sensor with an integrated multilayer metal-dielectric filter coating for providing a UV transmission curve of interest, such as the Erythema curve. The sensor includes a silicon-based photodiode monolithic with a filter coating comprising a plurality of metal-dielectric pairs stacked, in an alternating fashion, over the photodiode, where the thicknesses of the layers of each respective material (i.e., metal or dielectric) are different in different pairs. Thus, a specific set of metal-dielectric films is deposited directly on an active electronic substrate at least containing a silicon-based photodetector element in such a way as to provide precision UV measurement.

The specific metal-dielectric filter coatings described here provide multiple benefits such as e.g.: (1) provide specific UV filter curves such as for UVI, Vitamin D, UVA, UVB etc., (2) provide extremely high attenuation of all unwanted visible and NIR light so it can be used in full sunlight with no other auxiliary filters, (3) suppress scattered light from reaching the UV photodetector region because the coatings are deposited very close to the photodetector surface which suppresses the side-leakage of visible and NIR light, (4) layers are thin and robust to subsequent manufacturing process, allow easy lift-off to open other area on the wafer for other functions, and (5) due to the fact that the layers are thin, conformal coating can be done which when deposited on a “wavy” surface provides the functionality of a diffuser.

In order to measure UV radiation from the sun, optical filter coatings described herein can be provided to specifically measure a narrow band of wavelengths in the UVB and UVA portions of the spectrum. Such coatings have some unique characteristics, such as e.g. extremely high blockage of radiation in the visible portion of the sun's spectrum so that UV measurements are not “contaminated” by visible light, provision of very good representations of UVB, UVA, and Erythema weights so that UVI can be calculated with improved accuracy, and compatibility with high quality SiPD manufacturing process so that other optical sensors, such as gesture, proximity, optical heart rate and Photoplethysmography, ambient light sensors etc., can co-exist on the same die providing unique multi-dimensional measurement in a compact package.

A UV sensor using SiPD, e.g. a UV sensor for measuring UVI, should have a filter coating that has a transmission curve that substantially obeys a particular transmission curve of interest, such as e.g. the Erythema curve. The desired transmission curve can be achieved by controlling the thicknesses of the layers in the different metal-dielectric pairs stacked over a SiPD, in particularly by controlling that the thicknesses of the metal layers in the different metal-dielectric pairs are different from one another and, similarly, by controlling that the thicknesses of the dielectric layers in the different metal-dielectric pairs are also different from one another. Controlling the thicknesses of the metal and the dielectric layers to be different from the respective layers in other pairs results in that each pair contributes to a filter response at a different wavelength and angle of incidence, thus tuning the overall filter response to fit the desired curve of interest. Thus, the thickness variations of the metal and the dielectric layers in different pairs are controlled by design, as opposed to unpredictable and uncontrolled variations in these thicknesses which may result from e.g. variations in fabrication processes used to make the layers.

A very thin layer of metal may be almost transparent to UV but still block longer wavelength visible and IR light. A slightly thicker layer of metal may also absorb a significant portion of UV but still be advantageous for use in a UV filter because of the advantages such layers provide, as described in greater detail below. Thus, filter response is dependent on the thickness of the thin layer of metal and the dielectric sandwiching the layer of metal.

For some applications, it is desirable for filter coatings to be robust, i.e., wavelength response is preferably robust to small changes in the coating thickness variations, and relatively easy to make. Furthermore, it may be desirable for filter coatings to have low angle sensitivity. Low angle sensitivity is important and hard to realize as all thin film coatings have different wavelength response as the angle of incident changes due to the underlying physics of interference phenomena on which such coatings are based.

The metal-dielectric coating can be provided using, e.g., aluminum as the metal. Thin layers of aluminum can be deposited on SiPD in such a way so as to make these thin film coatings provide the required Erythema curve, block all visible and a substantial portion of UV, and are less angle sensitive, while more robust to manufacturing variations.

Layering Metal-Dielectric Coatings

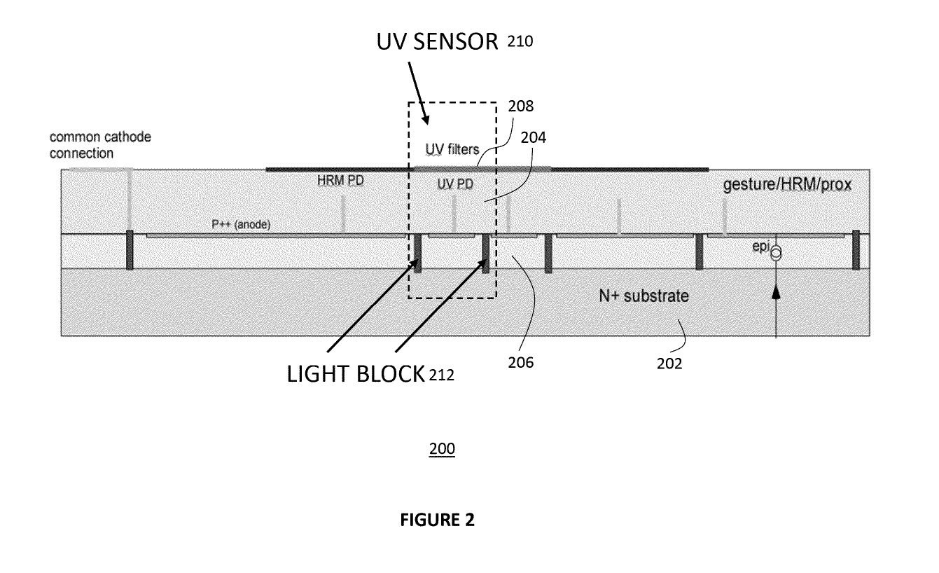

In an embodiment, to provide a filter coating an alternate layer of metal and UV transparent dielectrics such as hafnium dioxide, silicon nitride, oxides of tantalum, etc. are deposited. FIG. 2 shows a multilayer structure 200 of a plurality of photodiodes (not to scale), according to some embodiments of the disclosure. Typical silicon substrate (shown in FIG. 2 as a substrate 202) is 100's of micron thick which includes the SiPD 204 and the interlayer dielectric 206 that has wiring. Over the UV PD is a UV filter 208 according to the present disclosure. By using SiPD with the UV filter, it can be seen that multiple types of sensors 210 can be achieved using the same Si substrate.

FIG. 2 further illustrates an optional light block 212 placed around the UV PD region. The light block 212 may comprise metal films in order to block all light from reaching the UV PD from the sides and/or leaking through the inter layer dielectric.

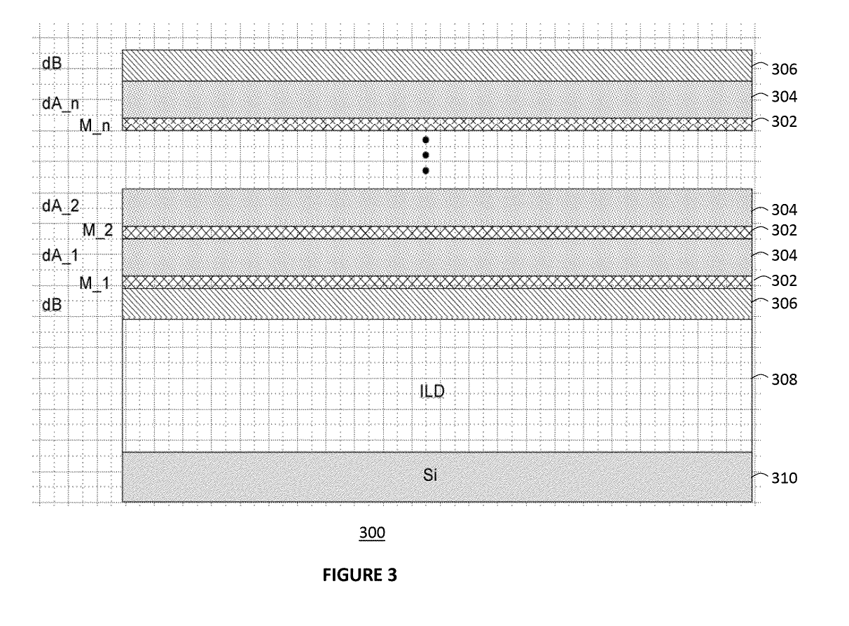

FIG. 3 shows a detailed multilayer structure 300 of an optical sensor with an improved coating, according to some embodiments of the disclosure. Zooming into the UV PD having the improved coating, FIG. 3 shows the layers of the improved filter coating. Specifically, the improved UV coating can have a general structure that looks like the one shown in FIG. 3. The letters M_1, M_2, . . . M_n represent metal layers 302, in this example aluminum (Al) layers, with different thickness typically of the order of 6-30 nm and the dA_1, dA_2, . . . dA_N represent the dielectric film layers 304, such as SiN, hafnium dioxide, etc., with thickness of the order of 30-50 nm. The entire stack may include repeated structure of the type metal-dielectric repeated between, e.g., 2-6 times with each layer having slightly different thickness. The stack itself may be sandwiched between dielectrics dB 306 in order to provide optical, mechanical or environmental compatibility to the stack itself. The UV coating is built on top of the interlayer dielectric (ILD) layers 308 which are part of standard SiPD manufacturing. The SiPD itself is any of p-n or p-i-n junction type structure on a bulk silicon or silicon-on-insulator (SOI) type substrate, shown in FIG. 3 as Si 310 (i.e., Si 310 is a block illustrating SiPD on a bulk silicon or (SOI) substrate).

Transmission Curves of Improved Filter Coating Resembling the Erythema Curve

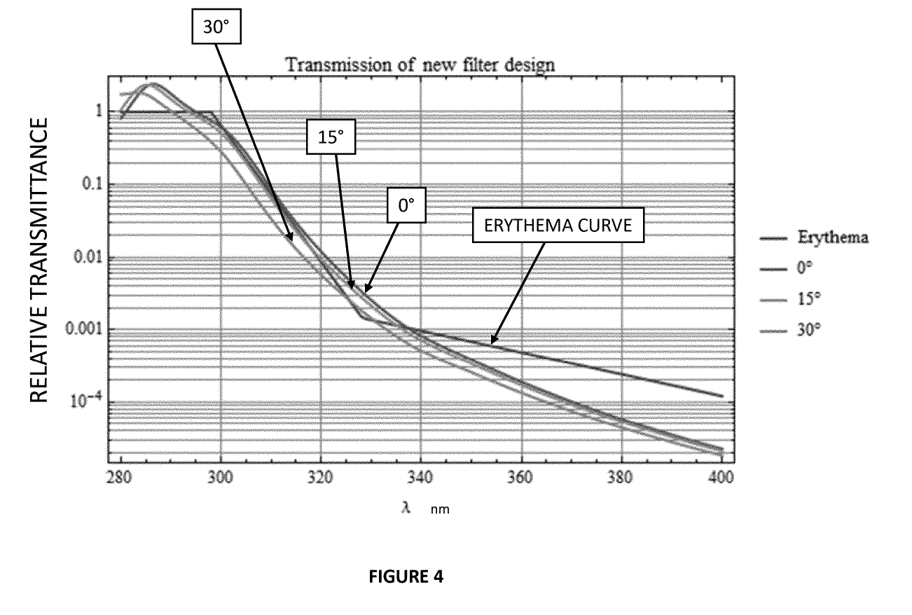

FIG. 4 is a graph showing an Erythema curve and transmission curves of light incident at an angle of 0°, 15°, and 30° using an optical sensor with an improved filter coating, according to some embodiments of the disclosure. In particular, transmission curves for the improved filter coating are shown. As an example, the transmission curves correspond to an illustrative filter coating design having specific layers: 4 repeated layers of Al and Hafnium dioxide HfO2 protected by glass. The 4 layer thickness for the Al are 27, 24.3, 29.7 and 29.7 nm and for Hafnium dioxide are 42, 37.9, 46.28, and 46.28 nm. Transmission curves for the illustrative filter coating are associated with results from light incident at 0 degree, 15 degree, and 30 degree angle of incidence. For reference, standard Erythema curve is also shown in FIG. 4. It is noted that there are many possibilities around similar numbers as actual refractive indices of the deposited films can be different than those used for generating the transmission curves of FIG. 4.

Due to the use of metal layers, the multilayer stacks as discussed above have fairly poor transmission. For example, for the stack shown above, typical peak transmission is of the order of a percent or so. Thus metal-dielectric pairs yield inefficient coatings and in general would not be desirable for UV measurement as stand-alone UV filters. However, the poor transmission is an acceptable trade-off in using metal-dielectric, e.g. Al-dielectric, filter coatings for UV measurement because of all the benefits this type of coating provides.

As previously described herein, an important feature of the improved filter coating is the use of different thicknesses in respective layers of different pairs to tune the filter response. From FIG. 4, it can be seen that a filter coating may be designed to follow the Erythema curve closely, thus providing an accurate UVI sensor.

In FIG. 4, the filter curve associated with the 30 degree angle of incidence begins to deviate from the target. While the results from the filter curve associated with the 30 degree angle of incidence performs reasonably well in following the Erythema curve, if higher accuracy is desired, one can consider adding certain features to the improved filter. The above curve comes to within a few percent of the ideal Erythema curve but may still suffer from angle sensitivity. At higher angles of incidence such as at 30 degrees, the curves may shift even further into the UV and the measured photocurrent may be reduced by more than the factor of Cos [30 Degrees]. For the above coatings, the measured photocurrent may be decreased by almost a half.

Light Block

Al is highly reflective and hence has very low transmission in the visible spectrum. In fact, in the visible spectrum, the transmission of a four layer Al film may be less than 10⁻⁵ and may easily approach 10⁻⁸, thus allowing to make UV measurements unhindered by the visible light. Furthermore, as illustrated in FIG. 2, an additional, optional, light block 212 can to be placed around the UV PD region consisting of all metal films so as to not let any light reach the UV PD from the sides and/or leak thru the ILD.

Improved Filter Coating with a Diffuser

FIG. 4 illustrated that the improved filter coating may have angle sensitivity. This angle sensitivity of the filter curve is built into the physics of the interference based thin film filters and is typically a disadvantage. However, embodiments of the present invention are based on an insight that this angle sensitivity could be turned into an advantage by purposefully adding angle variation to the incident light and averaging over all possible angles. In an embodiment, this can be done by providing a light diffusing surface, i.e., the optical sensor can be provided with a “built in” diffuser. There are multiple approaches of obtaining a light diffusing surface. Below, some approaches that are particularly suitable for use with metal dielectric coatings are described.

In a first approach, a light diffusing or scattering surface may be placed above the SiPD with the filter coating so that the light emerging from the diffuser is incident on the filter coating at various angles of incidence. In one example, such a diffuser could comprise ground glass. Teflon sheet is another example of a diffuser that works in the UV region. Such an approach would require additional glass optics to be placed near the UV optical detector and will likely diffuse light for other detectors on the same substrate, which may or may not be desirable. The second approach described below may improve on this potential problem.

In a second approach, a diffuser may be “built” on the SiPD substrate itself, thus providing a compact and cost-effective approach. In addition, this approach provides the advantage of the possibility to build such a diffuser only, or substantially, on the sensor of interest without interfering with the functionality of other sensors. In an embodiment, such a built-in diffuser may be provided by performing additional processing that adds topology to the SiPD wafer before depositing the filter coating film. The topology is then reflected in the topology of the surface layer of the filter coating, thereby reducing or eliminating angle sensitivity.

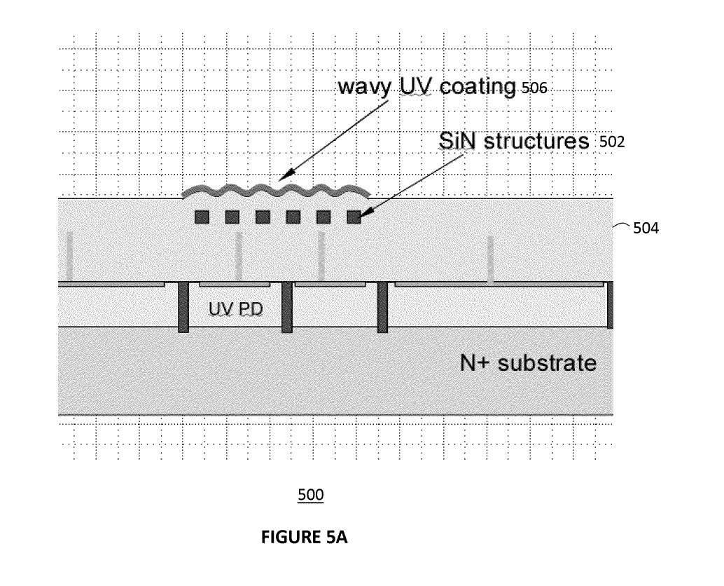

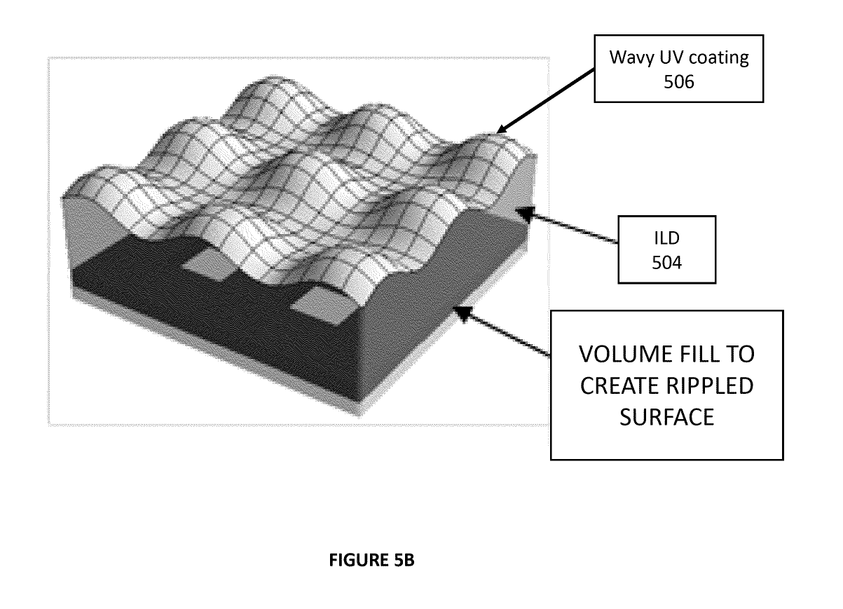

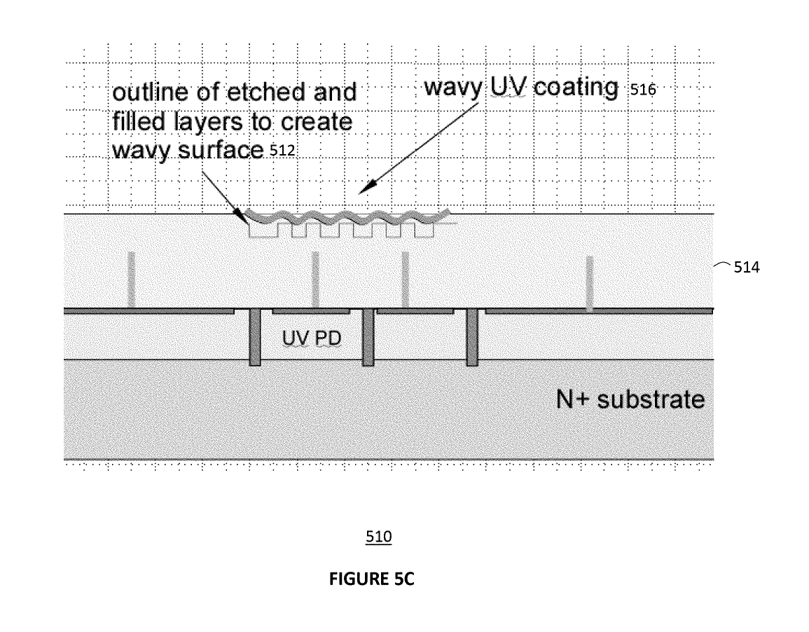

FIG. 5A shows a detailed multilayer structure 500 of an optical sensor with an improved filter coating having a diffuser, according to some embodiments of the disclosure. In this FIGURE, a SiN (which is transparent to UV) grid layer, indicated as SiN structures 502, is added on the wafer inside the ILD 504. In other words, a pattern of dielectric material is deposited in the ILD or embedded in the ILD. The pattern adds a pattern of extra volume and can make the surface of the filter coating uneven (e.g. bumpy or wavy) when the filter coating is deposited over the ILD, as shown in FIG. 5A with a wave UV coating 506. By adjusting the topology, e.g. pitch, thickness, and spatial arrangement, the grid layer can lead to a “wavy” top surface on which thin film stack of a filter coating is deposited. Thus, even if the light is incident to the entire SiPD at a particular incident angle, different angles of incidence are presented locally to the film stack and thus the response of the film is the average of many incident angles. Such an approach acts similar to a traditional diffuser placed separately from the detector surface as described in the first approach. The top surface can be bumpy, wavy, uneven, curvy, rippled, or other non-flat forms.

To view the diffuser from a different perspective, FIG. 5B shows a 3-dimensional model of the optical sensor with an improved filter coating having a diffuser such as the one shown in FIG. 5A. It can be seen that the top surface of the filter coating is rippled, and the ripples are formed by the volume created by the grid layer embedded in the ILD.

The second approach leads to angle average response that is almost independent of the angle and is equivalent to expensive diffusers seen in many UV measurement products. In practice, a two dimensional grid of these buries layers will have to be made to average over all angles. This “waviness” (i.e., unevenness) may be created by any means that generate topology including addition of material, as described above, or removal of material such as controlled etching of the ILD, as described below.

FIG. 5C shows a detailed multilayer structure 510 of an optical sensor with yet another improved filter coating having a diffuser, according to some embodiments of the disclosure. In FIG. 5C, the controlled etching of the ILD 514 is illustrated. Some of the ILD layers can be etched (shown as gray outline 512) and then filled by deposition to generate a smoother profile. The coatings are then deposited on such a profile, resulting in wavy UV coating 516.

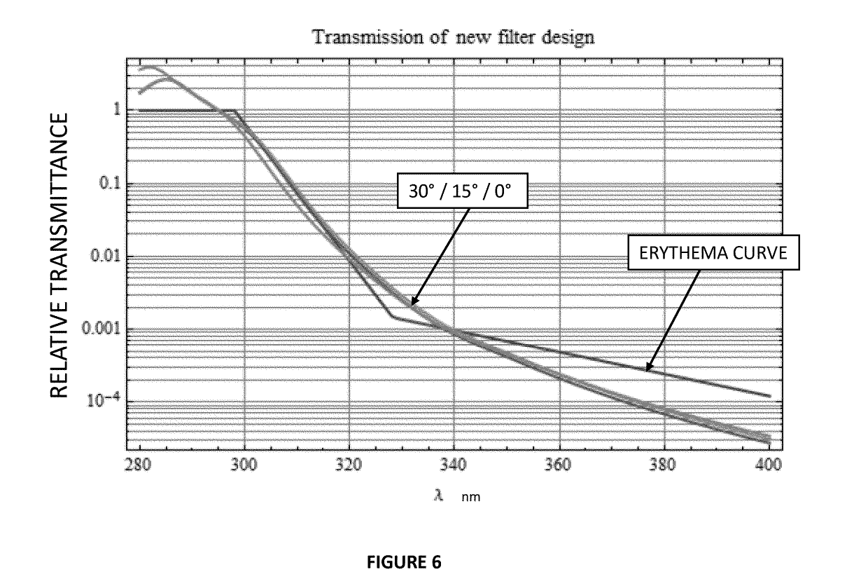

In both cases shown in FIGS. 5A and 5C, different layer thicknesses interact with different angles of light and by carefully choosing (i.e. controlling) the thickness of the layers, angle averaged response can be made very robust. FIG. 6 is a graph showing an Erythema curve and transmission curves of light being transmitted at an angle of 0°, 15°, and 30° using an optical sensor with an improved filter coating having a diffuser, according to some embodiments of the disclosure. It can been seen that the three transmission curves all similarly follow the Erythema curve. The difference in angle of incidence no longer significantly affects the performance of the transmission curves, as compared to the curves shown in FIG. 4.

The waviness is typically on a scale much larger (>5-10λ) than the wavelength of the light (>5-10λ) of interest so as to locally preserve a smooth surface and reduce losses from scattering. In some situations, it may be desirable for the uneven surface to provide local angle of incidence of zero degree to radiation that is incident on an average at angles as large as 30-45 degree. Thus, the amplitude of the waviness must be comparable to the undulation length. For a typical silicon manufacturing process, undulation length as well etch/deposition of materials will limit the scale to few microns or ˜10λ for UV wavelengths.

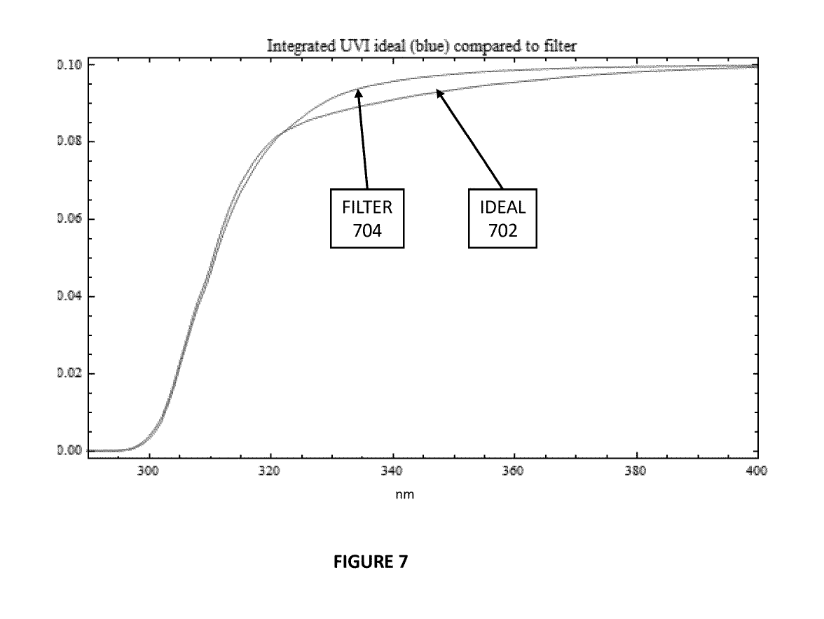

FIG. 7 is a graph comparing ideal UVI results 702 versus UVI results 704 obtained using an optical sensor with an improved filter coating having a diffuser, according to some embodiments of the disclosure. As shown in FIG. 7, the running integral of the equation for UVI calculation using the improved filter having the diffuser shows an excellent match with the ideal integral. The various curves in the above curve are for random 2% variations in the layer deposition. Thus, the improved filter coating with the diffuser proves to be a robust design in the presence of variations in the layer deposition.

Interactions Between the Different Thickness of Al and Diffuser

Three observations may be made with respect to the thin filter coating design. One is that a particular thicknesses of the metal and the dielectric layers in a particular metal-dielectric filter pair leads to a specific wavelength and angle of incidence dependence. Another observation is that multiple pairs of different thicknesses can be made to interact with one another to reduce angle dependence and provide, to a certain extent, built-in averaging to angles and wavelengths as well as robustness to small changes in stack parameters in actual manufacturing steps. A third observation is that providing many possible input angles by undulating the surface on which the coating is placed allows substantially averaging out the effects described in the first two observations, thereby providing a robust filter curve.

Improved Filter Coating Versus Other Solutions

Some sensors having SiPD with specialized coatings that mimic the Erythema curve and diffusers are usually provided in bulky packages. Some sensors uses other semiconductor PDs that are naturally transparent to visible light such as GaN and SiC. Both of these semiconductor materials are expensive and would require a separate die. With the improved filter coating according to various embodiments described herein, an optical sensor can be provided in a thin flat package with multiple sensor function, if needed, using SiPD.

Making Other Types of Sensors

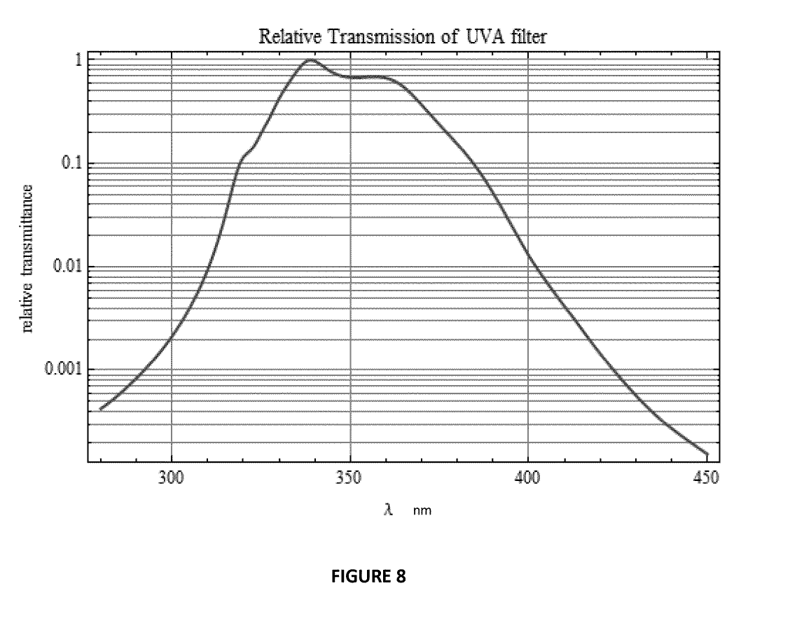

The central wavelength of the metal-dielectric pairs of a filter coating can be easily tuned to produce filters for different UV regions. Thus, the same type of coating stack can generate UVA measurement by changing the thicknesses of the layers, making it easy to streamline manufacturing and product planning. FIG. 8 is a graph showing an exemplary transmission curve of an optical sensor with an improved filter coating, according to some embodiments of the disclosure. In this case, the Al thicknesses for the stack are adjusted to a slightly smaller number and the hafnium dioxide thicknesses are increased, when compared with the example filter designs associated with the transmission curves shown in FIGS. 4 and 6. For this particular example, the thicknesses were 20, 20.2, 20.6, and 21 nm for Al and 63, 63.7, 65, and 66.2 nm for hafnium dioxide layers.

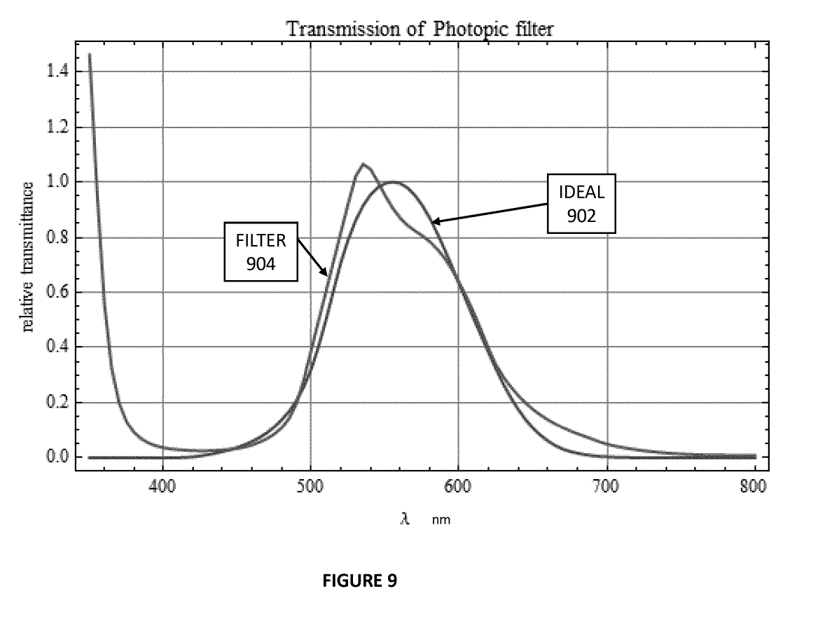

The filter design described herein is quite flexible. For example, a filter coating can be provided to respond to the same wavelengths as the human eye. This is called the Photopic response. By using the same filter structure but reducing the Al thickness to 9, 8.1, 9.9, and 9.45 and hafnium dioxide to 122, 110.2, 134.7, and 128.5 nm, the photopic response can be reproduced. FIG. 9 is a graph showing an ideal transmission curve 902 of a photopic filter and a transmission curve 904 of an optical sensor with an improved filter coating, according to some embodiments of the disclosure. Using very thin layers of metal may let some UV light through, as evidenced by the response in FIG. 9 below 400 nm. The UV response can be easily suppressed by using UV opaque materials, of which there are many, or by using a type of SiPD that has very poor response to UV, which can also be relatively easy to do. Also, for most light sources, including sun, there is very little light in the UV to make any appreciable difference in the measurement.

There is a range of metal thicknesses that provide a particular functionality and, therefore, enable a filter in a particular spectral region. For Al, thickness in each layer is preferably less than 40 nm and is in the range of 7-12 nm for visible light filters to approximately 20 nm (e.g. 20-40 nm) for UV filters. The thickness of the dielectric is then chosen to match the required filter. The dielectric thickness would typically be larger for filters of longer wavelengths (i.e., larger dielectric thicknesses for visible light filters, smaller dielectric thicknesses for UV filters), contrary to the metal thicknesses where, e.g. Al, thickness is chosen to be smaller for longer wavelength filters. This is because of a complex interplay of attenuation in metal and its refractive index which are both strong functions of wavelength.

### VARIATIONS AND IMPLEMENTATIONS

In certain contexts, the optical sensor discussed herein can be applicable to medical systems, scientific instrumentation, industrial process control, audio and video equipment, consumer electronics, etc. In particular, mobile devices or compact electronics can greatly benefit from the ability to provide a variety of specialized optical sensors (i.e., sensors made with SiPD with different filter coatings) in one die with a small flat form factor. Moreover, certain embodiments discussed above can be used in patient monitoring, medical instrumentation, and home healthcare. This could include heart rate monitors, pulse oximetry meters, etc. Other applications can involve automotive technologies for safety systems (e.g., stability control systems, driver assistance systems, braking systems) and user interface applications of any kind.

In yet other example scenarios, the teachings of the present disclosure can be applicable in the industrial markets that include process control systems that help drive productivity, energy efficiency, and reliability, via the use of optical sensors. In consumer applications, the teachings of the signal processing circuits discussed above can be used for image processing, auto focus, and image stabilization (e.g., for digital still cameras, camcorders, etc.). Other consumer applications can include optical sensing for home theater systems, DVD recorders, and high-definition televisions. Yet other consumer applications can involve optical controllers (e.g., for any type of portable media device). Hence, such technologies could readily part of smartphones, tablets, security systems, PCs, gaming technologies, virtual reality, simulation training, etc.

In the discussions of the embodiments above, various materials, components, and parts can readily be replaced, substituted, or otherwise modified in order to accommodate particular needs of an optical sensor.

In one example embodiment, any number of optical sensors and associated electronic circuitry of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), computer-readable non-transitory memory elements, etc. can be suitably coupled to the board based on particular configuration needs, processing demands, computer designs, etc. Other components such as external storage, additional sensors, controllers for audio/video display, and peripheral devices may be attached to the board as plug-in cards, via cables, or integrated into the board itself.

In another example embodiment, the optical sensors, electrical circuits, and components of the FIGURES may be implemented as stand-alone modules (e.g., a device with associated components and circuitry configured to perform a specific application or function) or implemented as plug-in modules into application specific hardware of electronic devices. Note that particular embodiments of the present disclosure may be readily included in a system on chip (SOC) package, either in part, or in whole. An SOC represents an IC that integrates components of a computer or other electronic system into a single chip. It may contain digital, analog, mixed-signal, and often radio frequency functions: all of which may be provided on a single chip substrate. Other embodiments may include a multi-chip-module (MCM), with a plurality of separate ICs located within a single electronic package and configured to interact closely with each other through the electronic package.

It is also imperative to note that all of the specifications, dimensions, and relationships outlined herein (e.g., the number of processors, logic operations, etc.) have only been offered for purposes of example and teaching only. Such information may be varied considerably without departing from the spirit of the present disclosure, or the scope of the appended claims (if any) and/or sample embodiments (if any). The specifications apply only to one non-limiting example and, accordingly, they should be construed as such. In the foregoing description, example embodiments have been described with reference to particular processor and/or component arrangements. Various modifications and changes may be made to such embodiments without departing from the scope of the appended claims (if any) and/or sample embodiments (if any). The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

It is also important to note that the operations related to fabricating the optical sensors, illustrate only some of the possible operations that may be performed to produce the optical sensors. Some of these operations may be deleted or removed where appropriate, or these operations may be modified or changed considerably without departing from the scope of the present disclosure. In addition, the timing of these operations may be altered considerably. The operations related to fabricating the optical sensors have been offered for purposes of example and discussion. Substantial flexibility is provided by embodiments described herein in that any suitable arrangements, chronologies, configurations, and timing mechanisms may be provided without departing from the teachings of the present disclosure. Numerous other changes, substitutions, variations, alterations, and modifications may be ascertained to one skilled in the art and it is intended that the present disclosure encompass all such changes, substitutions, variations, alterations, and modifications as falling within the scope of the appended claims (if any) and/or sample embodiments (if any). Note that all optional features of the apparatus described above may also be implemented with respect to the method or process described herein and specifics in the examples may be used anywhere in one or more embodiments.

What is claimed is:

1. A silicon-based sensor with an integrated multilayer metal-dielectric filter coating for providing an ultraviolet (UV) transmission curve of interest, the sensor comprising:
a silicon-based photodiode; and
a filter coating integrated with the silicon-based photodiode and comprising a plurality of filter pairs stacked over the silicon-based photodiode,
wherein:
each filter pair comprises a dielectric layer and a metal layer,
the dielectric layers and the metal layers of the plurality of filter pairs are stacked in an alternating fashion,
a thickness of the metal layer in at least one filter pair is different from a thickness of the metal layer in at least one other filter pair, and
a thickness of the dielectric layer in at least one filter pair is different from a thickness of the dielectric layer in at least one other filter pair.

2. The silicon-based sensor according to claim 1, wherein a thickness of the metal layer in at least one filter pair is selected so that transmission of light in a visible and near-infrared (NIR) spectrum is below 10⁻⁴.

3. The silicon-based sensor according to claim 2, wherein the visible and NIR spectrum comprises wavelength in the range greater than 400 nanometers (nm).

4. The silicon-based sensor according to claim 2, wherein the filter coating comprises an uneven top surface for diffusing light transmitted through the filter coating.

5. The silicon-based sensor according to claim 1, wherein the filter coating comprises an uneven top surface for diffusing light transmitted through the filter coating.

6. The silicon-based sensor according to claim 5, wherein the uneven top surface is formed by a pattern of a dielectric material deposited within or over the silicon-based photodiode prior to providing the plurality of filter pairs stacked over the silicon-based photodiode.

7. The silicon-based sensor according to claim 5, wherein the uneven top surface is formed by a pattern etched within the silicon-based photodiode prior to providing the plurality of filter pairs stacked over the silicon-based photodiode.

8. The silicon-based sensor according to claim 1, wherein a thickness of the metal layer in at least one filter pair and/or a thickness of the dielectric layer in at least one filter pair are/is selected to provide the transmission curve of interest.

9. The silicon-based sensor according to claim 1, wherein the transmission curve of interest comprises a Erythema curve, a Photopic curve, a Photosynthesis inhibition curve, a Vitamin D production curve, a bandpass response for passing Ultraviolet A light, or a bandpass response for passing Ultraviolet B light.

10. The silicon-based sensor according to claim 1, wherein the metal layers comprise aluminum layers.

11. The silicon-based sensor according to claim 1, wherein the dielectric layers include one or more of the following materials: hafnium dioxide, silicon nitride, aluminum oxide, and oxides of tantalum.

12. The silicon-based sensor according to claim 1, further comprising a first dielectric layer and a second dielectric layer sandwiching the plurality of filter pairs.

13. A device comprising:
a substrate;
a first silicon-based photodiode provided in or on the substrate;
one or more second silicon-based photodiodes provided in or on the substrate; and
a filter coating for providing a ultraviolet (UV) transmission curve of interest, the filter coating integrated with the first silicon-based photodiode and comprising a plurality of filter pairs stacked over the first silicon-based photodiode,
wherein:
each filter pair comprises a dielectric layer and a metal layer,
the dielectric layers and the metal layers of the plurality of filter pairs are stacked in an alternating fashion,
a thickness of the metal layer in at least one filter pair is different from a thickness of the metal layer in at least one other filter pair, and
a thickness of the dielectric layer in at least one filter pair is different from a thickness of the dielectric layer in at least one other filter pair;
wherein the one or more second silicon-based photodiodes form one or more sensors other than sensors for providing the UV transmission curve of interest.

14. The device according to claim 13, wherein the one or more second silicon-based photodiodes comprise one or more of a gesture sensor, a photopic sensor, an ambient light sensor, a heartrate detector sensor, a red light sensor, and a proximity sensor.

15. The device according to claim 14, wherein the substrate comprises a silicon on insulator (SOI) substrate or a bulk silicon substrate.

16. A method for fabricating a silicon-based sensor with an integrated multilayer metal-dielectric filter coating for providing a ultraviolet (UV) transmission curve of interest, the method comprising:
providing a silicon-based photodiode; and
providing a filter coating integrated with the silicon-based photodiode by stacking a plurality of filter pairs of the filter coating over the silicon-based photodiode,
wherein:
each filter pair comprises a dielectric layer and a metal layer,
the dielectric layers and the metal layers of the plurality of filter pairs are stacked in an alternating fashion,
a thickness of the metal layer in at least one filter pair is different from a thickness of the metal layer in at least one other filter pair, and
a thickness of the dielectric layer in at least one filter pair is different from a thickness of the dielectric layer in at least one other filter pair.

17. The method according to claim 16, further comprising depositing a pattern of a dielectric material within or over the silicon-based photodiode prior to stacking the plurality of filter pairs stacked over the silicon-based photodiode.

18. The method according to claim 16, further comprising etching a pattern within the silicon-based photodiode prior to providing the plurality of filter pairs stacked over the silicon-based photodiode.

19. The method according to claim 16, further comprising selecting a thickness of the metal layer in at least one filter pair and/or a thickness of the dielectric layer in at least one filter pair to provide the transmission curve of interest.

20. The method according to claim 16, wherein the transmission curve of interest comprises a Erythema curve, a Photopic curve, a Photosynthesis inhibition curve, a Vitamin D production curve, a bandpass response for passing Ultraviolet A light, or a bandpass response for passing Ultraviolet B light.
